(19) United States
(12) Patent Application Publication
(10) Pub. No.: US 2025/0386569 A1
(43) Pub. Date: Dec. 18, 2025

(54) TRENCH BASED SEMICONDUCTOR DEVICES WITH INCREASED PLANARITY

(71) Applicant: Wolfspeed, Inc., Durham, NC (US)

(72) Inventors: Rahul R. Potera, Apex, NC (US); Madankumar Sampath, Durham, NC (US); Thomas Harrington, Durham, NC (US); Elizabeth Philip, Durham, NC (US)

(21) Appl. No.: 18/742,626

(22) Filed: Jun. 13, 2024

(51) Int. Cl. H01L 29/10; H01L 29/06; H01L 29/16; H01L 29/808

(52) U.S. Cl. CPC H10D 62/343; H10D 30/831; H10D 62/107; H10D 62/8325

(57) ABSTRACT

A semiconductor device includes a semiconductor layer having an active region and a gate contact region adjacent the active region, a plurality of alternating mesa stripes and trenches in the active region, a gate contact pad on the semiconductor layer, and an under-gate mesa in the gate contact region beneath the gate contact pad. The semiconductor device may have a saw street at an outer periphery of the semiconductor layer, wherein a top surface of the saw street is at a same height above the substrate as top surfaces of the plurality of mesa stripes.

### TECHNICAL FIELD

The present disclosure relates to semiconductor devices and, more particularly, to power semiconductor devices having gate resistors.

### BACKGROUND

A wide variety of power semiconductor devices are known in the art including, for example, power Junction Field Effect Transistors (“JFETs”), power Metal Oxide Semiconductor Field Effect Transistors (“MOSFETs”), Insulated Gate Bipolar Transistors (“IGBTs”) and various other devices. These power semiconductor devices are often fabricated from wide bandgap semiconductor materials. Herein, the term “wide bandgap semiconductor” encompasses any semiconductor having a bandgap of at least 1.4 eV. Power semiconductor devices are designed to selectively block or pass large voltages and/or currents. For example, in the blocking state, a power semiconductor device may be designed to sustain hundreds or thousands of volts of electric potential.

Power semiconductor devices having high power ratings are most typically fabricated using silicon carbide, as silicon carbide has a number of advantageous characteristics including, for example, a high electric field breakdown strength, high thermal conductivity, high electron mobility, high melting point and high-saturated electron drift velocity. A conventional silicon carbide-based power semiconductor device typically has a silicon carbide substrate, such as a silicon carbide wafer having a first conductivity type (e.g., an n-type substrate), on which a silicon carbide epitaxial layer structure is formed which may have both first and second conductivity type layers and/or regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

The epitaxial layer structure of most power semiconductor devices includes a drift region and an “active region” that is formed on and/or in the drift region. The active region acts as a main junction for blocking voltage during off-state operation (also referred to as “reverse bias” or “reverse blocking” operation) and current flows through the active region during on-state operation (also referred to as “forward bias” operation). Most power semiconductor devices also have an edge termination region adjacent the active region. The edge termination region is designed to spread the electric fields during reverse blocking operation out over a greater area in order to reduce electric field crowding effects that would otherwise occur along the outer edges of the active region. One or more power semiconductor devices may be formed on the wafer, and each power semiconductor device will typically have its own edge termination region. After the epitaxial layer(s) is/are grown on the wafer and fully processed, the wafer may be diced to separate the individual edge-terminated power semiconductor devices if multiple devices are formed on the same wafer (or other substrate). The power semiconductor devices may have a unit cell structure in which the active region of each power semiconductor device includes a large number of individual cells that are disposed in parallel to each other and that together function as a single power semiconductor device.

A vertical JFET is a three terminal device that has gate, drain and source terminals that are formed on a semiconductor layer structure, which typically comprises a semiconductor substrate with epitaxial layers formed thereon. Source regions that are electrically connected to the source terminal and a drain region that is electrically connected to the drain terminal may be formed in the semiconductor layer structure. A plurality of channel regions are interposed in the semiconductor layer structure between the source regions and the drain region. A gate structure of the vertical JFET may include, for example, a gate bond pad that serves as the gate terminal, a gate pad that is connected to the gate bond pad, a plurality of gate contacts, and one or more gate buses and/or gate contacts that electrically connect the gate pad to the gate contacts. The gate contacts are disposed adjacent the respective channel regions. Power JFETs are typically normally-on devices, meaning that a JFET conducts current when a voltage of 0 volts is applied to the gate structure.

### SUMMARY

A semiconductor device according to some embodiments includes a semiconductor layer having an active region and a gate contact region adjacent the active region, a plurality of alternating mesa stripes and trenches in the active region, a gate contact pad on the semiconductor layer, and an under-gate mesa in the gate contact region beneath the gate contact pad.

The semiconductor device may further include an insulating layer between the under-gate mesa and the gate contact pad.

The under-gate mesa may be electrically isolated from the plurality of alternating mesa stripes in the active region.

The under-gate mesa may include an extension of one of the plurality of alternating mesa stripes in the active region.

The under-gate mesa may have a width in the gate contact region that is greater than a width of mesa stripes in the active region.

At least one of the mesa stripes of the plurality of alternating mesa stripes in the active region extends into the gate contact region and beneath the gate contact pad.

The under-gate mesa may have a width that is less than a width of mesa stripes in the active region.

A doping concentration in the under-gate mesa may be lower than a doping concentration of mesa stripes in the active region.

The semiconductor device may further include a plurality of alternating under-gate mesas and first trenches in the gate contact region beneath the gate contact pad, wherein the first trenches have a width that is less than a width of the plurality of trenches in the active region.

The semiconductor device may further include a substrate, wherein the semiconductor layer is on the substrate, and a saw street at an outer periphery of the semiconductor device, wherein a top surface of the saw street is at a same height above the substrate as top surfaces of the plurality of mesa stripes.

A semiconductor device according to some embodiments includes a semiconductor layer having an active region and a gate contact region adjacent the active region, a plurality of alternating mesa stripes and trenches in the active region, and a gate contact pad on the semiconductor layer. At least one mesa stripe of the plurality of mesa stripes extends beneath the gate contact pad.

The semiconductor device may further include an insulating layer between the under-gate mesa and the gate contact pad.

The under-gate mesa may have a width beneath the gate contact pad that is greater than a width of mesa stripes in the active region.

The under-gate mesa may have a width that is less than a width of mesa stripes in the active region.

A semiconductor device according to further embodiments includes a substrate, a semiconductor layer on the substrate, the semiconductor layer having an active region and an edge termination region surrounding the active region, a plurality of alternating mesa stripes and trenches in the active region, and a gate contact pad on the semiconductor layer, and a saw street at an outer periphery of the semiconductor layer. A top surface of the saw street is at a same height above the substrate as top surfaces of the plurality of mesa stripes.

The semiconductor device may be a junction field effect transistor, and the saw streets at the outer periphery of the semiconductor layer may be at drain potential of the semiconductor device.

The semiconductor device may further include an under-gate mesa in the gate contact region beneath the gate contact pad.

The semiconductor device may further include an insulating layer between the under-gate mesa and the gate contact pad.

The under-gate mesa may be electrically isolated from the plurality of alternating mesa stripes in the active region.

The under-gate mesa may be an extension of one of the plurality of alternating mesa stripes in the active region.

The under-gate mesa may have a width in the gate contact region that is greater than a width of mesa stripes in the active region.

At least one of the mesa stripes of the plurality of alternating mesa stripes in the active region may extend into the gate contact region and beneath the gate contact pad.

The under-gate mesa may have a width that is less than a width of mesa stripes in the active region.

### BRIEF DESCRIPTION OF DRAWINGS

FIG. 1 illustrates a cell of a vertical JFET semiconductor device.

FIG. 2 illustrates, in plan view, a layout of a vertical JFET semiconductor device.

FIG. 3 is a cross sectional illustration of portions of a vertical JFET semiconductor device.

FIG. 4 illustrates, in plan view, a layout of a vertical JFET device according to some embodiments.

FIGS. 5 and 6 are cross sectional illustrations of portions of the vertical JFET semiconductor device shown in FIG. 4.

FIG. 7 illustrates, in plan view, a layout of a vertical JFET device according to further embodiments.

FIG. 8 is a cross sectional illustration of portions of the vertical JFET semiconductor device shown in FIG. 7.

FIGS. 9 and 10 illustrate, in plan view, layout of a vertical JFET device according to further embodiments.

FIG. 11 is a cross sectional illustration of portions of the vertical JFET semiconductor device shown in FIG. 10.

### DETAILED DESCRIPTION

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Although some embodiments are described in the context of a silicon carbide JFET device, it will be appreciated that aspects of the inventive concepts may be applicable to other types of devices that include mesas and trenches, such as vertical MOSFETs, insulated gate bipolar transistors (IGBTs) and other types of devices.

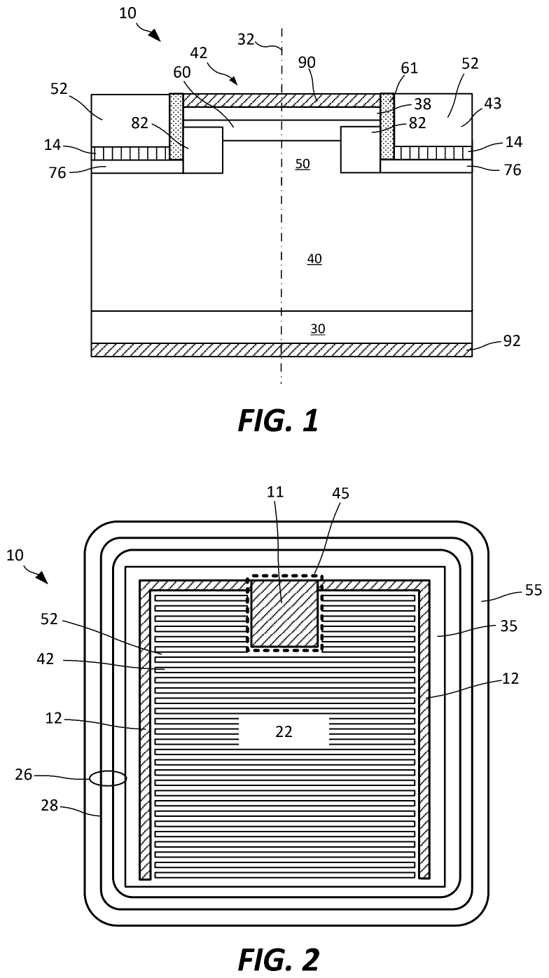

An n-channel vertical JFET structure 10 is shown in FIG. 1. The vertical JFET structure 1 includes an n+substrate 30 on which an n-drift layer 40 is formed. An n-type channel region 50 is on the drift layer 40, and an n+source layer 60 is on the channel region 50. An n++ source contact layer 38 is on the n+ source layer 60. A drain ohmic contact 92 is on the substrate 30, and a source ohmic contact 90 is on the source contact layer 38. The channel region 50, source layer 60 and source contact layer 38 are provided as part of a mesa stripe 42 above the drift layer 40. Trenches 52 are formed in the structure 10 adjacent the mesa stripe 42.

A p+ gate region 82 is provided as part of the mesa stripe 42 adjacent the channel region 50. A p++ gate contact region 76 is provided adjacent the gate region 82, and a gate ohmic contact, or gate finger, 14 is formed on the gate contact region 76 in the trenches 52 on opposite sides of the mesa stripe 42. To form the gate finger 14, a layer of metal, such as nickel (Ni), is deposited on the upper surfaces of the gate contact regions 76 and patterned appropriately. The metal is then annealed (for example, by being subjected to high temperature for a period of time) to form metal silicide layers on the upper surfaces of the gate contact regions 76, which provide ohmic contacts to the underlying layers.

An insulation layer 43 is formed in the trenches 52 on the gate finger 14 and the gate contact region 76. The insulation layer 43 may be formed, for example, from silicon oxide. In some embodiments, the insulation layer 43 may be a borophosphosilicate glass (BPSG), which is a type of silicate glass that includes additives of both boron and phosphorus. Oxide/nitride spacer layers 61 are provided on sidewalls of the mesa stripe 42.

The vertical JFET unit cell structure 10 is symmetrical about the axis 32 and includes two gate regions 82 as part of the mesa stripe 42 on opposite sides of the channel region 50.

The channel region 50 of the vertical JFET structure 10 is formed within the mesa stripe 42 between the gate regions 82. The channel width is into the plane of FIG. 1, and the channel length is in the vertical direction from the source region 60 to the drift layer 40. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A p-channel JFET may have a similar structure, but the conductivity types are reversed from those shown in FIG. 1.

In operation, conductivity between the source layer 60 and the substrate 30 is modulated by applying a reverse bias to the gate regions 82 relative to the source layer 60. To switch off an n-channel device such as the JFET structure 10, a negative gate-to-source voltage (or gate voltage) Vos is applied to the gate regions 82. When no voltage is applied to the gate region 82, charge carriers can flow freely from the source layer 60 through the channel region 50 and the drift layer 40 to the substrate 30.

FIG. 2 illustrates, in plan view, a conventional layout of a vertical JFET semiconductor device 10. Referring to FIG. 2, a JFET device 10 is formed on a substrate 30. The device 10 includes an active region 22 in which a plurality of alternating mesa stripes 42 and trenches 52 are formed. The active region 22 is surrounded by an edge termination region 26 in which a plurality of guard rings 28 are formed. Guard rings 28 are shown as an example of an edge termination for a power semiconductor device. However, other termination structures, such as field rings, junction termination extension (JTE) regions, etc., can be provided in the edge termination region 26.

A silicide region 35 is formed on an upper surface of the device within the active region 22 in areas other than on the mesa stripes 42. The silicide region 35 forms the gate fingers 14 within the trenches 52.

A gate contact pad 11 is formed on the upper surface of the device 10 in a gate contact region 45 within the silicide region 35, and a pair of gate buses 12 (also referred to as gate runners 12) extend from the gate contact pad 11 around the outer periphery of the active region 22 adjacent the ends of the mesa stripes 42 and trenches 52 of the device 10. The gate contact pad 11 and the gate buses 12 may include a conductive material such as a metal silicide and/or a metal layer.

The silicide region 35 provides a low resistance current path between the gate buses 12/gate contact pad 11 and the gate fingers 14 (FIG. 1) that are formed within the trenches 52.

In the JFET device 10, a gate voltage applied to the gate contact pad 11 is conducted through the gate bus 12 and silicide region 35 to the gate ohmic contacts 14 within the trenches 52.

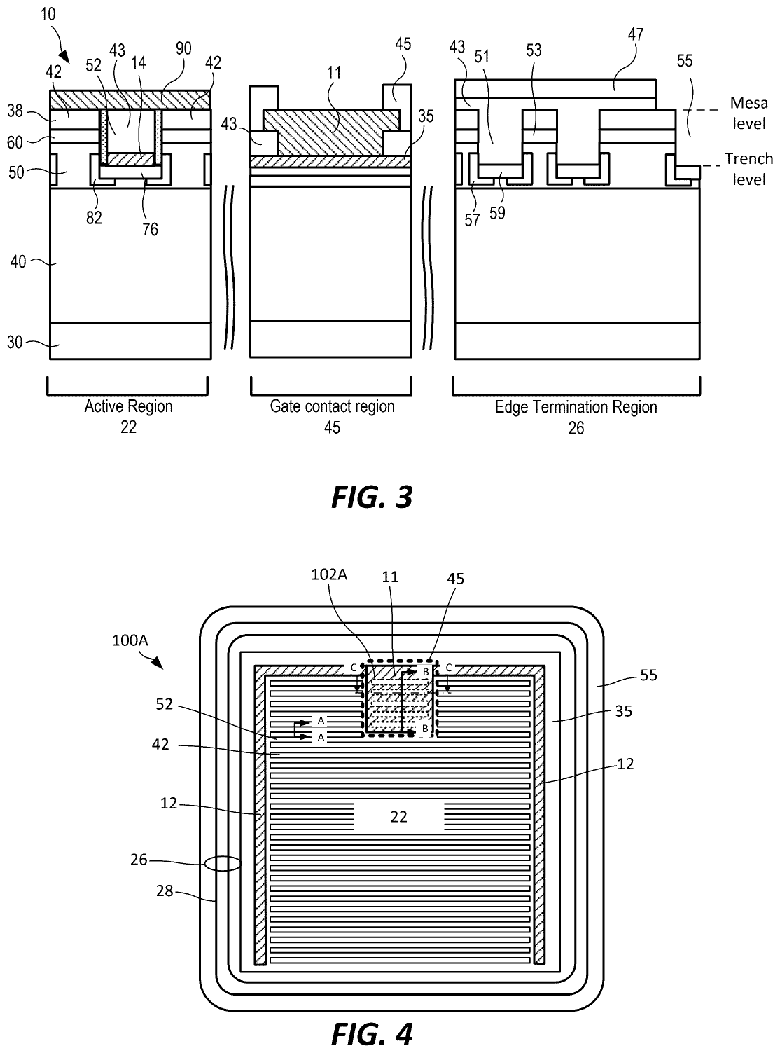

FIG. 3 is a cross-sectional illustration of portions of the JFET device 10 of FIG. 2. In particular, FIG. 3 is a cross-section of a portion of the device 10 in the active region 22, a portion of the device 10 beneath the gate pad 11 in the gate pad region 45, and a portion of the device 10 in the edge termination region 35.

As seen in FIG. 3, due to the formation of the mesa stripes 42 and trenches 52, the top surface of the device 10 generally includes two levels above the substrate 30, namely, a mesa level corresponding to the top surfaces of the mesa stripes 42, and a trench level corresponding to the bottom surfaces of the trenches 52. It will be appreciated that there may be small variations in the height of the trench level from region to region due to silicidation of semiconductor material in the silicide region 35.

The gate contact pad 11 contacts the silicide region 35 though an opening in an interlayer dielectric layer 47.

Both the active region 22 and the edge termination region 26 may include mesas and trenches. For example, the active region 22 includes the active mesa stripes and trenches 52, while the edge termination region 26 may include alternating mesa rings 53 and trench rings 51. Trench implants 59 and sidewall implants 57 are formed in the trench rings 51 in the edge termination region 26 in the same process in which the gate contact regions 76 and sidewall gate regions 82 are formed in the active region 22.

In a conventional structure as shown in FIG. 3, the entire gate pad region 45 beneath the gate contact is at the trench level, and the saw street 55 at the edges of the device 10 outside the edge termination region 26 is also at the trench level.

A trench-mesa based semiconductor device, such as the JFET device 10 illustrated in FIGS. 1 and 2, is formed using various photolithographic operations that involve coating a wafer with a photoresist material. This is typically performed using a spin coating process in which the wafer is rotated at a high angular velocity (e.g., 500 rpm or more) as a liquid solution of photoresist and solvent is applied to the wafer. Centripetal force due to the rotation of the wafer combined with the surface tension of the solution pulls the liquid coating into an even covering over the wafer. Afterwards, the solvent evaporates, leaving a thin film of photoresist on the wafer.

In a trench-mesa based semiconductor device, photolithography levels that are performed subsequent to the mesa etch may need to coat photoresist over high aspect ratio mesas. This can present certain challenges, as photoresist may pool inside the trenches, and/or radial streaks may form in the photoresist due to the unevenness of the wafer surface after trench formation. This may make patterning beyond the mesa etch step difficult. Moreover, a lack of a sufficiently thick carbonized resist cap can cause step-bunching during photoresist activation, and resist pooling can make patterning narrow features difficult.

Some embodiments described herein provide trench-mesa based semiconductor device designs that may reduce topological variations across a wafer surface by providing mesas beneath a gate pad in a gate pad region of the device. This may reduce the occurrence of resist streaking by elevating surfaces beneath the gate pad of the JFET to the mesa level. Moreover, elevating dicing streets between JFET devices on a wafer to mesa level may also reduce the occurrence of resist streaking.

In some embodiments, additional floating or source-connected mesas, referred to herein as under-gate mesas, are provided beneath the gate pad of the semiconductor device. The under-gate mesas do not contact the gate metal. By providing the under-gate mesas in the gate region, the portion of the wafer and die that is etched down to the trench level is reduced, which may reduce the occurrence of resist streaking. In embodiments in which the under-gate mesas are connected to the active region mesas, the active area of the device may be increased as a proportion of die area.

In some embodiments, the under-gate mesas may have lower channel doping than the mesas in the active region. With lower channel doping, the pinch-off voltage of the under-gate mesas can be higher, so that they can be kept in an “off” state even when maximum gate to source voltage (Vgs) is applied to the device.

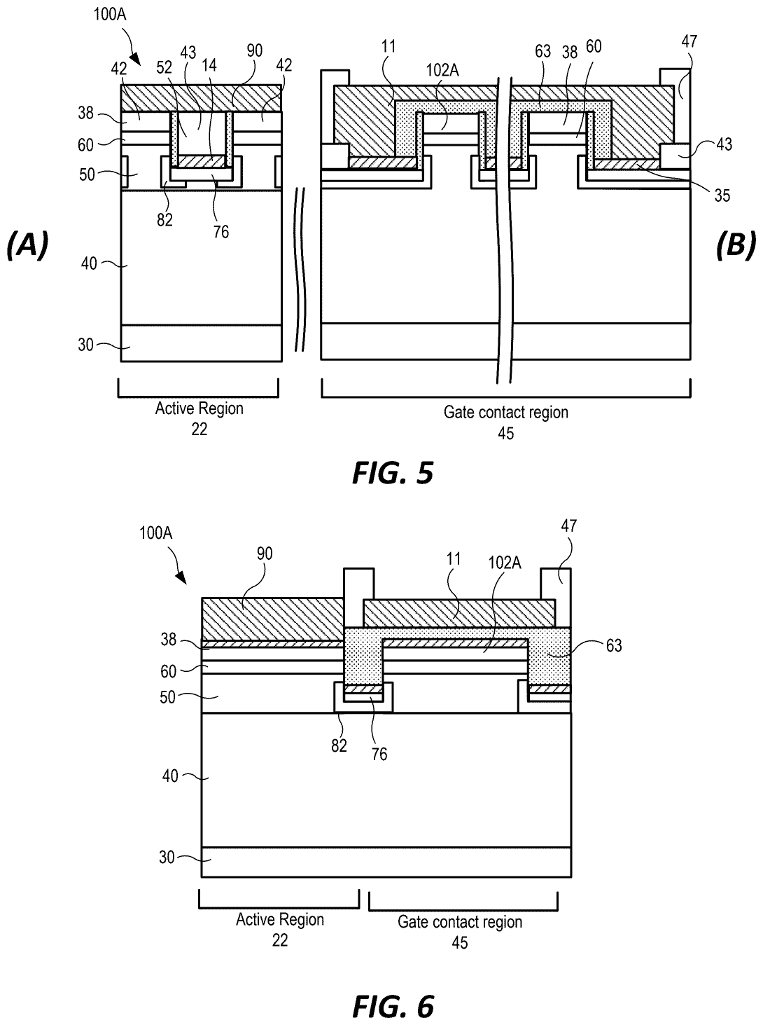

FIG. 4 is a plan view of a device 100A including a plurality of mesas 102A that are formed in the gate contact region 45, referred to herein as under-gate mesas 102A. FIGS. 5A and 5B are cross-sections of portions of the device 100A taken along lines A-A, and B-B of FIG. 4, respectively. FIG. 6 is a cross section of the device 100A taken along line C-C of FIG. 4.

In the embodiments illustrated in FIGS. 4-6, the under-gate mesas 102A are formed as floating mesas that are not connected to the mesa stripes 42 in the active region 22. The under-gate mesas 102A may be formed using the same fabrication processes used to form the mesa stripes 42, except that the under-gate mesas 102A may have a lower channel doping. For example, the channel regions 50 of the mesa stripes 42 may be doped at a doping concentration of about 5E15 cm-3 to 1E17 cm-3, and the under-gate mesas may be doped at a doping concentration of less than about 1E15 cm-3 to 5E16 cm-3.

The lower channel doping in the under-gate mesas 102A may be selected to cause the under-gate mesas 102A to remain in a pinched off condition even with Vgs at a maximum level (Vgsₘₐₓ).

As illustrated in FIGS. 5 and 6, no via is opened through the insulation layer 43 to the top of the under-gate mesas 102A that would allow the gate contact 11 to contact the top surfaces of the under-gate mesas 102A. Rather, a via 77 is opened in the insulation layer 43 adjacent to the under-gate mesas 102A to allow the gate contact pad 11 to contact the silicide region 35.

As further shown in FIG. 4, the under-gate mesas 102A may be arranged to run in the same direction as the mesa stripes 42. However, in some embodiments, the under-gate mesas 102A may be not run in the same direction as the mesa stripes 42.

By providing under-gate mesas 102A, the overall topographical uniformity of the wafer may be increased, and photoresist material that is spin-coated onto the wafer containing the device 100A may be applied with greater thickness uniformity.

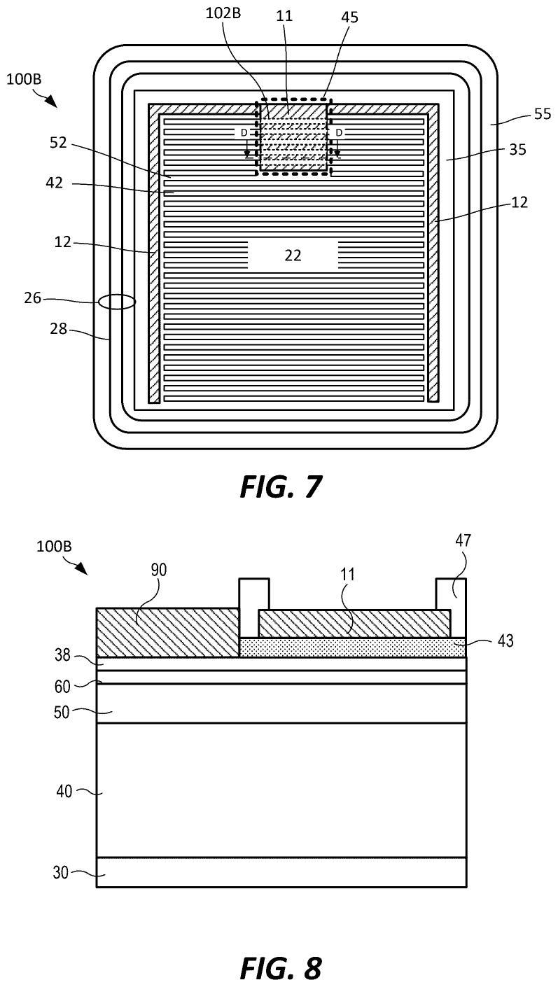

FIG. 7 is a plan view of a device 100B including under-gate mesas 102B in the gate contact pad region 45 that connect to the mesa stripes 42 in the active region 22, and FIG. 8 is a cross section of the device 100B taken along line D-D of FIG. 7.

In the embodiments illustrated in FIGS. 7 and 8, the mesa stripes 42 run under the gate pad 11 to provide the under-gate mesas 102B. The under-gate mesas 102B are separated from the gate contact pad by the insulation layer 43 because no via is opened under the gate contact pad 11 over the under-gate mesas 102B. Rather, a via may be opened in the insulation layer 43 adjacent to the under-gate mesas 102A to allow the gate contact pad 11 to contact the silicide region 35.

In the embodiments shown in FIGS. 7 and 8, channel doping is still present in the under-gate mesas 102B, and the under-gate mesas 102B conduct just like the mesa stripes 42, thereby reducing on-resistance of the device 10. Since the source contact is only made through the silicide region 35 to the under-gate mesas 102B, they do not conduct as well as the mesa stripes 42 in the active region 22. However, any amount of conduction through the under-gate mesas 102B may help reduce the on-resistance of the device 10. The under-gate mesas 102B may run parallel to the upper side of the gate contact pad 11 as shown in FIG. 7, or they may be normal to it.

By providing the under-gate mesas 102B, the overall topographical uniformity of the wafer may be increased, and photoresist material that is spin-coated onto the wafer containing the device 100B may be applied with greater thickness uniformity.

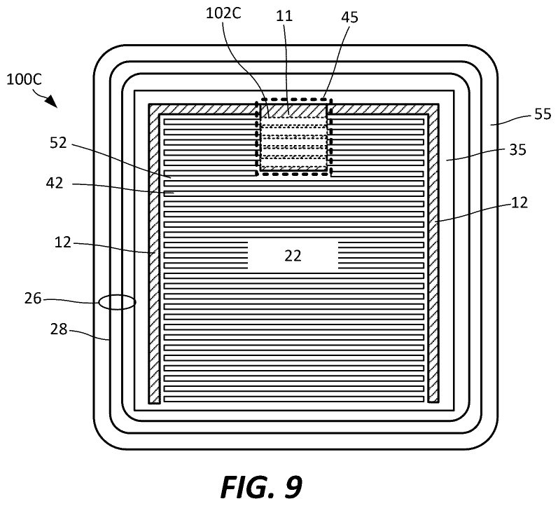

FIG. 9 is a plan view of a device 100C including under-gate mesas 102C according to further embodiments.

In embodiments shown in FIG. 9, the under-gate mesas 102C are widened and the trenches between the under-gate mesas 102C are narrowed. In particular, the under-gate mesas 102C are widened and the trenches between the under-gate mesas are narrowed as far as possible without significant change to the threshold voltage V_{T}, (e.g., to about 0.1 microns to 0.2 microns) so that the thickness of the insulation layer 63 over the mesas and under gate pad can be increased, because narrower trenches lead to a thicker insulation layer 63 (shown in FIG. 6). A thicker insulation layer 63 will increase the voltage blocking capability between the gate pad 11 and the mesas 102C under the gate pad 11. The under-gate mesas 102C may run along the side of the gate pad 11 as shown in FIG. 9, or normal to it.

By providing the under-gate mesas 102C, the overall topographical uniformity of the wafer may be increased, and photoresist material that is spin-coated onto the wafer containing the device 100C may be applied with greater thickness uniformity.

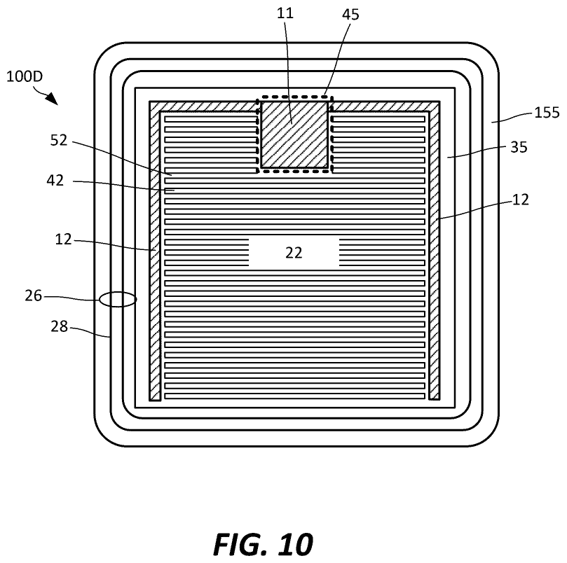

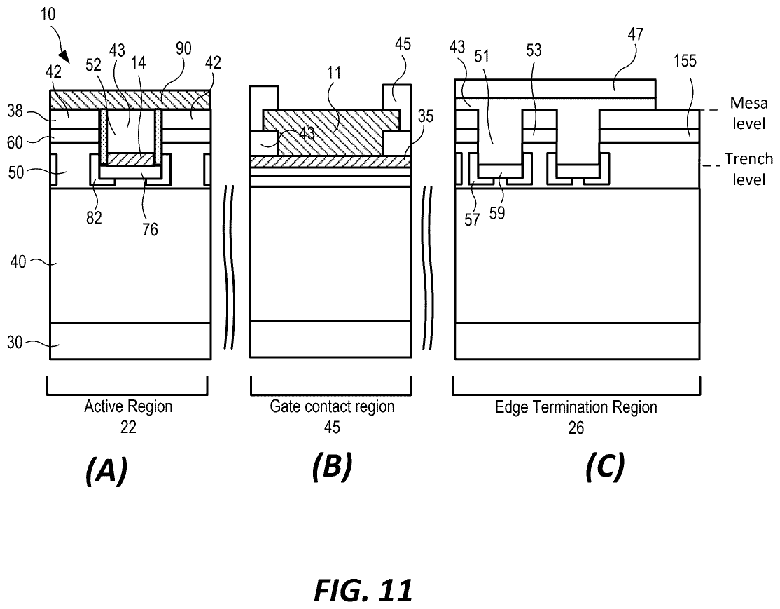

FIG. 10 is a plan view of a device 100D in which the saw streets 155 are formed at mesa level. In this embodiment, gate pad 11 is similar to a traditional JFET, however, the street region 155 between devices is raised to the mesa level. The streets 155 will therefore be at drain potential. By raising the streets 155 to mesa level, photoresist material that is spin-coated onto the wafer may be applied with greater thickness uniformity.

Although no under-gate mesas are illustrated in FIG. 10, it will be appreciated that under-gate mesas may be provided in the device 100D to further increase the uniformity of photoresist material that is spin coated onto the wafer containing the device 100D.

The inventive concepts have been described above with reference to the accompanying drawings, in which embodiments are shown. The inventive concepts may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout, except where expressly noted.

It will be understood that although the terms first and second are used herein to describe various regions, layers and/or elements, these regions, layers and/or elements should not be limited by these terms. These terms are only used to distinguish one region, layer or element from another region, layer or element. Thus, a first region, layer or element discussed below could be termed a second region, layer or element, and similarly, a second region, layer or element may be termed a first region, layer or element without departing from the scope of the present invention.

Relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if the device in the drawings is turned over, elements described as being on the “lower” side of other elements would then be oriented on “upper” sides of the other elements. The exemplary term “lower” can, therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The term “in electrically conductive contact” means that two elements are in direct or indirect contact in such a way that electrical current can flow from one element to another. At least part of the connection between the two elements may be electrically resistive.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, elements, and/or components, but do not preclude the presence or addition of one or more other features, elements, components, and/or groups thereof.

Embodiments of the inventive concepts are described herein with reference to cross-sectional illustrations that are schematic illustrations. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Thus, the regions illustrated in the figures are schematic in nature and their shapes are not intended to illustrate the actual shape of a region of a device and are not intended to limit the scope of the invention.

It will be understood that the embodiments disclosed herein can be combined. Thus, features that are pictured and/or described with respect to a first embodiment may likewise be included in a second embodiment, and vice versa.

While the above embodiments are described with reference to particular figures, it is to be understood that some embodiments of the present invention may include additional and/or intervening layers, structures, or elements, and/or particular layers, structures, or elements may be deleted. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

1. A semiconductor device, comprising:
a semiconductor layer having an active region and a gate contact region adjacent the active region;
a plurality of alternating mesa stripes and trenches in the active region;
a gate contact pad on the semiconductor layer; and
an under-gate mesa in the gate contact region beneath the gate contact pad.

2. The semiconductor device of claim 1, further comprising an insulating layer between the under-gate mesa and the gate contact pad.

3. The semiconductor device of claim 1, wherein the under-gate mesa is electrically isolated from the plurality of alternating mesa stripes in the active region.

4. The semiconductor device of claim 1, wherein the under-gate mesa comprises an extension of one of the plurality of alternating mesa stripes in the active region.

5. The semiconductor device of claim 4, wherein the under-gate mesa has a width in the gate contact region that is greater than a width of mesa stripes in the active region.

6. The semiconductor device of claim 1, wherein at least one of the mesa stripes of the plurality of alternating mesa stripes in the active region extends into the gate contact region and beneath the gate contact pad.

7. The semiconductor device of claim 1, wherein the under-gate mesa has a width that is less than a width of mesa stripes in the active region.

8. The semiconductor device of claim 1, wherein a doping concentration in the under-gate mesa is lower than a doping concentration of mesa stripes in the active region.

9. The semiconductor device of claim 1, wherein the semiconductor device further comprises a plurality of alternating under-gate mesas and first trenches in the gate contact region beneath the gate contact pad, wherein the first trenches have a width that is less than a width of the plurality of trenches in the active region.

10. The semiconductor device of claim 1, further comprising:
a substrate, wherein the semiconductor layer is on the substrate; and
a saw street at an outer periphery of the semiconductor device, wherein a top surface of the saw street is at a same height above the substrate as top surfaces of the plurality of mesa stripes.

11. A semiconductor device, comprising:
a semiconductor layer having an active region and a gate contact region adjacent the active region;
a plurality of alternating mesa stripes and trenches in the active region; and
a gate contact pad on the semiconductor layer;
wherein at least one mesa stripe of the plurality of mesa stripes extends beneath the gate contact pad.

12. The semiconductor device of claim 11, further comprising an insulating layer between the gate contact pad and a portion of the at least one mesa stripe that extends beneath the gate contact pad.

13. The semiconductor device of claim 11, wherein a portion of the at least one mesa stripe that extends beneath the gate contact pad has a width beneath the gate contact pad that is greater than a width of mesa stripes in the active region.

14. The semiconductor device of claim 11, wherein a portion of the at least one mesa stripe that extends beneath the gate contact pad has a width that is less than a width of mesa stripes in the active region.

15. A semiconductor device, comprising:
a substrate;
a semiconductor layer on the substrate, the semiconductor layer having an active region and an edge termination region surrounding the active region;
a plurality of alternating mesa stripes and trenches in the active region;
a gate contact pad on the semiconductor layer within a gate contact region; and
a saw street at an outer periphery of the semiconductor layer, wherein a top surface of the saw street is at a same height above the substrate as top surfaces of the plurality of mesa stripes.

16. The semiconductor device of claim 15, wherein the semiconductor device comprises a junction field effect transistor, and wherein the saw streets at the outer periphery of the semiconductor layer are at drain potential of the semiconductor device.

17. The semiconductor device of claim 15, further comprising:
an under-gate mesa in the gate contact region beneath the gate contact pad.

18. The semiconductor device of claim 17, further comprising an insulating layer between the under-gate mesa and the gate contact pad.

19. The semiconductor device of claim 17, wherein the under-gate mesa is electrically isolated from the plurality of alternating mesa stripes in the active region.

20. The semiconductor device of claim 17, wherein the under-gate mesa comprises an extension of one of the plurality of alternating mesa stripes in the active region.

21. The semiconductor device of claim 20, wherein the under-gate mesa has a width in the gate contact region that is greater than a width of mesa stripes in the active region.

22. The semiconductor device of claim 17, wherein at least one of the mesa stripes of the plurality of alternating mesa stripes in the active region extends into the gate contact region and beneath the gate contact pad.

23. The semiconductor device of claim 17, wherein the under-gate mesa has a width that is less than a width of mesa stripes in the active region.
